(19) United States
(12) Patent Application Publication
(10) Pub. No.: US 2008/0261112 A1
(43) Pub. Date: Oct. 23, 2008

(54) ELECTRODE MATERIAL FOR ELECTROCHEMCIAL DEVICE, METHOD FOR PRODUCING THE SAME, ELECTRODE USING THE ELECTRODE MATERIAL, AND ELECTROCHEMICAL DEVICE USING THE ELECTRODE MATERIAL

(76) Inventors: Kaoru Nagata, Osaka (JP); Takashi Otsuka, Osaka (JP)

Correspondence Address: MCDERMOTT WILL & EMERY LLP, 600 13TH STREET, NW, WASHINGTON, DC, 20005-3096, US

(21) Appl. No.: 12/105,045

(22) Filed: Apr. 17, 2008

(30) Foreign Application Priority Data
Apr. 17, 2007 (JP) 2007-107923

(51) Int. Cl. H01M 4/38; C23C 16/22; H01B 1/06; H01G 9/00

(52) U.S. Cl. 429/218.1; 252/500; 252/502; 252/503; 427/578; 361/502

(57) ABSTRACT

An electrode material of the present invention includes a plurality of particles capable of absorbing and desorbing lithium, and a plurality of nanowires capable of absorbing and desorbing lithium. The particles and the nanowires include silicon atoms. The plurality of nanowires are entangled with each other to form a network, and the network is in contact with at least two of the plurality of particles.

### FIELD OF THE INVENTION

The present invention relates mainly to an electrode material for electrochemical devices and a method for producing the electrode material. To be specific, the present invention relates to an improvement of an electrode material for electrochemical devices.

### BACKGROUND OF THE INVENTION

Nowadays, electronic devices such as personal computers and cell phones are rapidly becoming portable, and for a power source for driving such devices, a small and lightweight but high capacity electrochemical device has been demanded.

For a material that achieves such an electrochemical device, silicon, which is capable of absorbing and desorbing lithium ions, has been gaining attention. For example, silicon has been gaining attention as a negative electrode active material for achieving a high capacity non-aqueous electrolyte secondary battery. This is because the theoretical discharge capacity of silicon is about 4199 mAh/g, and this is more than ten times the theoretical capacity of carbon materials, which are widely used as a negative electrode active material currently. Silicon can also be used as a negative electrode material for lithium ion electric double layer capacitors, utilizing its lithium ion absorbing and desorbing characteristics.

Also becoming increasingly important is development of electrochemical devices such as varistors, in which ceramics and semiconductors such as silicon are layered and which is used for stabilizing voltage and protecting circuits in electronic devices.

However, when silicon is used as for example an alloy-type negative electrode material for non-aqueous electrolyte secondary batteries, silicon undergoes significant expansion and contraction when absorbing and desorbing lithium ions. For example, the silicon volume expands to approximately four times the original volume by absorbing lithium ions. Thus, negative electrode active material particles crack, or the active material layer is peeled off from the current collector, declining the electron conductivity between the active material and the current collector. As a result, battery performance such as cycle performance declines.

Thus, there has been an attempt to decrease the volume change due to the lithium ion absorption and desorption, by using an oxide, nitride, or oxynitride of silicon or tin as the negative electrode active material, despite a slight decline in discharge capacity.

Also, there has been an attempt to provide a space in the active material layer in advance to absorb the volume expansion when lithium ions are taken in.

For example, Japanese Laid-Open Patent Publication No. 2003-303586 (document 1) discloses a secondary battery electrode formed by depositing a thin film comprising an active material on the current collector. To be specific, in document 1, the columnar projection portions of a predetermined pattern are formed on a thin film of active material. With the gaps between the columnar projection portions, the volume expansion of the active material is absorbed. Thus, the active material expansion and contraction do not give a large stress to the current collector, and the damage of the active material can be avoided. Document 1 describes that the columnar projection portions are formed by the lift-off method.

Nanostructured anode material for lithium-ion batteries (G. X. Wang and four others, International Meeting on Lithium Batteries 2006 abstracts, issued by Centre National de la Recherche Scientifique, France, 2006, p. 325) (document 2) disclosed a use of a mixture made by dispersing nano-sized silicon in aerosol containing carbon powder to make a composite electrode plate for use as a negative electrode of a lithium secondary battery. It further discloses a negative electrode for a lithium secondary battery obtained by sublimating silicon powder, and attaching silicon nanowire thinly on a stainless steel. Document 2 reports that the use of silicon nanowires achieves obtaining a capacity of 3000 mAh/g and excellent cycle performance. In the manufacturing method disclosed in document 2, only silicon nanowires are formed.

Silicon nanowires can also be made as in below.

For example, Japanese Laid-Open Patent Publication No. Hei 10-326888 (document 3) discloses a method in which nano-sized molten alloy drops are formed on a substrate as a catalyst, and SiH₄ is supplied to allow silicon nanowires to grow below each molten alloy drop. In this producing method as well, only silicon nanowires are formed on the substrate.

Japanese Laid-Open Patent Publication No. 2005-112701 (document 4) discloses a method in which silicon powder is sintered in a furnace of 1200° C. to obtain a sintered body, and this sintered body is evaporated in an inert gas flow to allow silicon nanowires to grow on a substrate disposed at a position where a temperature gradient of 10° C./cm or more is present within a temperature range between 1200° C. to 900° C. In this producing method as well, only silicon nanowires are produced.

As disclosed in document 1, providing gaps in the active material layer is effective for absorbing the active material volume expansion when lithium ions are taken in. However, when the active material layer has a plurality of scattered columnar projection portions and the cross section of the columnar projection portion is large, the active material particles themselves are vulnerable to damage by the expansion. On the other hand, when the cross section of the columnar projection portion is small, adhesiveness at the interface between the current collector and the active material declines, easily causing the removal of the active material from the current collector.

Silicon in nanowire form is more promising compared with those highly rigid columnar particles in that silicon in nanowire form is flexible. However, characteristics of silicon nanowires are yet to be understood sufficiently. Further, there are rooms for improvement in terms of characteristics necessary for developing silicon nanowires for usage in devices.

For example, in the case of the electrode plate containing only silicon nanowires as the negative electrode active material, as disclosed in document 2, with only the nanowires, the adhesiveness between the current collector and the active material is low. Thus, when the active material expansion and contraction are caused by charge and discharge, the active material is easily removed from the current collector, declining cycle performance. Further, due to the large surface area of silicon nanowires, silicon nanowires are partially oxidized to become silicon oxide. Silicon oxide has a large irreversible capacity, which declines battery capacity.

In the case of the manufacturing method of nanowires as disclosed in document 3, since the silicon nanowires are formed below the catalyst, a catalyst of molten metal such as Au and Al has to be formed on the substrate with a predetermined pattern. Further, as a raw material for nanowires, expensive and dangerous gas such as silane is necessary.

In the case of the manufacturing method of nanowires disclosed in document 4, a step for attaching nanowires to the substrate becomes necessary.

The present invention aims to solve the problems in developing silicon nanowires for use in devices such as those mentioned in the above, for example, the problem caused by the expansion of the electrode material in electrochemical devices, and the problem of an increase in irreversible capacity. To be specific, the present invention aims to provide an electrode for an electrochemical device with a high battery capacity or capacitance, and provide a simple manufacturing method thereof.

### BRIEF SUMMARY OF THE INVENTION

An electrode material for electrochemical devices of the present invention includes a plurality of particles capable of absorbing and desorbing lithium, and a plurality of nanowires capable of absorbing and desorbing lithium. The particles and the nanowires contain silicon atoms. The plurality of nanowires are entangled with each other to form a network, and the network is in contact with at least two of the plurality of particles.

In a preferred embodiment of the present invention, the particles and the nanowires further contain at least one element selected from the group consisting of oxygen, carbon, and nitrogen atoms.

In another preferred embodiment of the present invention, at least one of the particles and the nanowires further contain a metal element other than the silicon.

The present invention also relates to an electrode for electrochemical devices. The electrode contains the electrode material and a carrier for carrying the electrode material. The carrier preferably includes at least one material selected from the group consisting of copper, nickel, and stainless steel.

The present invention further relates to an electrochemical device including the electrode, a counter electrode, and an electrolyte. The electrochemical device is preferably a non-aqueous electrolyte secondary battery or an electric double layer capacitor.

The present invention further relates to a method for producing the electrode material. The method includes the steps of:

(a) generating a thermal plasma in an atmosphere including an inert gas;

(b) placing a raw material containing silicon in the thermal plasma; and

(c) depositing a product obtained by allowing the raw material to pass through the thermal plasma on a predetermined carrier.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE SEVERAL VIEWS OF THE DRAWING

FIG. 1 is a schematic diagram illustrating an electrode material in one embodiment of the present invention.

FIG. 2 is an electron micrograph illustrating an electrode material in one embodiment of the present invention.

FIG. 3 is an electron micrograph illustrating nanowires entangled with each other to form a network, contained in an electrode material in one embodiment of the present invention.

FIG. 4 is a schematic diagram illustrating an example of a manufacturing device for producing an electrode material of the present invention.

FIG. 5 is a vertical cross section schematically illustrating a coin-type test battery made in Examples.

### DETAILED DESCRIPTION OF THE INVENTION

In the following, the present invention is described in detail with reference to the FIGs.

An electrode material for electrochemical devices of the present invention includes a plurality of particles capable of absorbing and desorbing lithium ions, and a plurality of nanowires capable of absorbing and desorbing lithium ions. The particles and nanowires include silicon atoms. Further, the plurality of nanowires are entangled with each other to form a network, and the network is in contact with at least two of the plurality of particles.

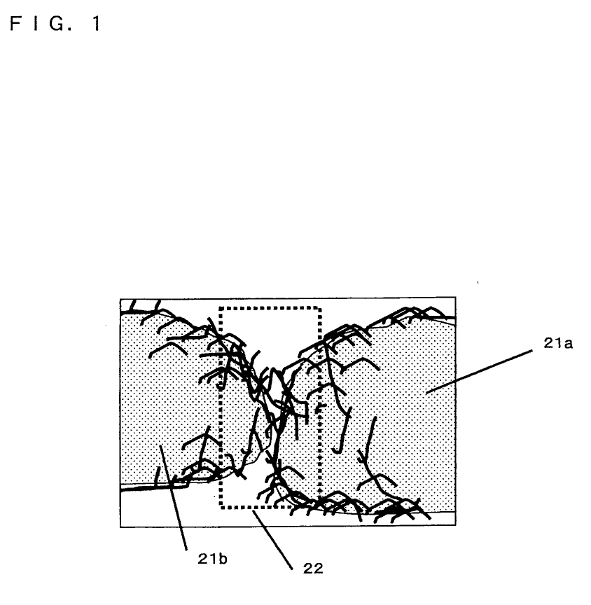

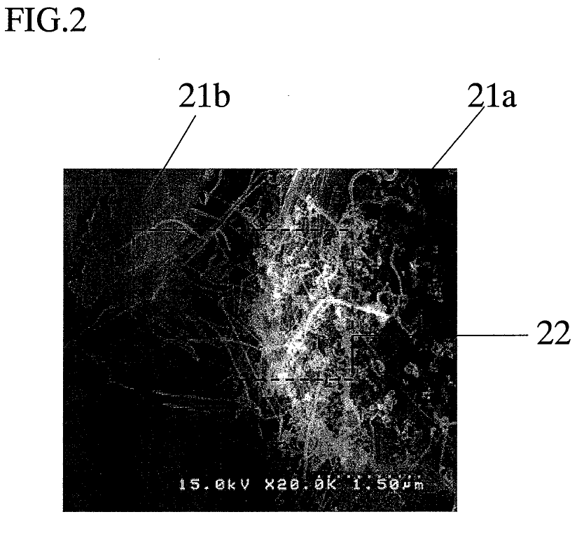

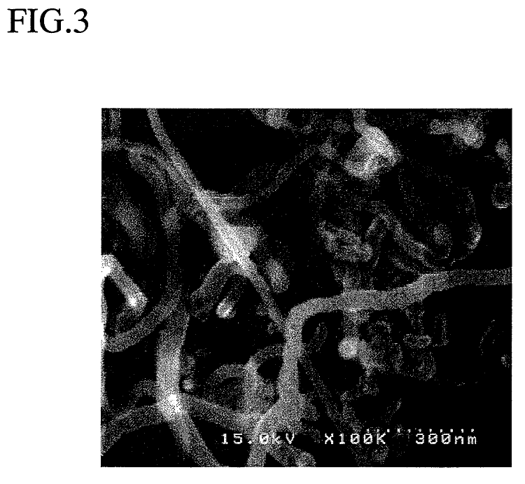

FIG. 1 schematically illustrates an electrode material in one embodiment of the present invention, and FIG. 2 illustrates an electron micrograph of an electrode material in one embodiment of the present invention. FIG. 3 illustrates an electron micrograph of an example of a network of nanowires contained in an electrode material in one embodiment of the present invention.

As shown in FIGS. 1 to 3, in an electrode material of the present invention, a plurality of particles and a nanowire network are entangled with each other. To be specific, as shown in the electron micrograph of FIG. 3, a plurality of nanowires are entangled with each other to form a nanowire network 22. The nanowire network 22 connects a particle 21a and a particle 21b. That is, the nanowire network 22 is in contact with at least two particles capable of absorbing and desorbing lithium ions, i.e., the particles 21a and 21b.

The particle diameter of the particles is preferably 0.5 to 10 μm. Although the fiber diameter of the nanowires is not particularly limited, it is preferably 10 nm to 500 nm, and further preferably 20 to 50 nm. The fiber length of the nanowires is not particularly limited and may be selected as appropriate, as long as the network can be formed. For example, the fiber length of the nanowires is preferably 0.1 to 10 μm.

The particle diameter of the particles, and the fiber diameter and the fiber length of the nanowires can be determined by, for example, observation with an electron microscope. The particle diameter of the particles can be determined, for example, by determining the maximum diameters of ten particles in the particles, and calculating the average of the obtained maximum diameters. The fiber diameter and the fiber length of the nanowires can also be determined in the same manner.

The weight ratio of the particles to the nanowires is preferably 85:15 to 45:55.

As described above, in the present invention, the nanowires entangled with each other to form a network are in contact with at least two particles. Since the particle diameter of the particles is small, the particles can be brought into contact with the carrier with an appropriate contact area. Thus, even when the particles expand, the particles can be brought into close contact with the carrier. Further, the nanowire network is entangled with the particles. Thus, the separation of these materials from the carrier can be curbed.

That is, based on the present invention, even with the repetitive expansion and contraction of the electrode material, a high capacity electrode in which the separation of the electrode material from the carrier is curbed can be provided. By using such an electrode, reliability of the electrochemical device, for example, in terms of cycle performance, can be improved.

The particles and the nanowires include silicon atoms. For example, the particles and the nanowires may be composed only of silicon atoms. Or, at least one of the particles and the nanowires may include silicon atoms and an element other than silicon atoms. The element is preferably at least one of, for example, oxygen, carbon, and nitrogen. The element does not absorb or desorb lithium ions. Therefore, by including the element in at least one of the particles and the nanowires, the volume change of the particles and the nanowires at the time of charge and discharge can be made small. The amount of the element may be appropriately selected according to the volume change rate and the battery capacity.

For example, the composition of the particles and the nanowire is preferably SiOₓ (0≦x<2), SiN_{y} (0<y<1), or SiC_{z} (0<z<1).

Or, at least one of the particles and the nanowires may include a metal atom other than a silicon atom. By including a metal atom in the particles and the nanowires, the electrical resistance between the particles and the nanowires can be made small.

For the metal atom included in the particles and the nanowires, copper, nickel, and iron may be mentioned. The amount of the metal atom is selected appropriately based on the expansion rate and the discharge capacity of the particles and the nanowires.

The electrode material may be used for an electrode for electrochemical devices. The electrode for electrochemical devices may include, for example, the electrode material and a conductive carrier carrying the electrode material. For the material forming the carrier, various metal materials such as copper, nickel, iron, and stainless steel; and carbon materials may be used.

To be specific, the electrode material of the present invention may be used, for example, as a negative electrode active material for non-aqueous electrolyte secondary batteries. For the material forming the conductive carrier (negative electrode current collector) carrying the electrode material, for example, copper, nickel, and iron may be mentioned.

The non-aqueous electrolyte secondary battery may include a negative electrode containing the electrode material of the present invention, a positive electrode, i.e., a counter electrode, and an electrolyte. The positive electrode includes a positive electrode active material capable of absorbing and desorbing lithium ions. For the positive electrode active material, for example, LiCoO₂, LiNiO₂, LiNi_{1/2}Mn_{1/2}O₂, and LiNi_{0.5}Co_{0.5}O₂ may be used, but not limited to these materials.

The electrolyte includes a non-aqueous solvent and a solute dissolved therein. For the non-aqueous solvent, for example, ethylene carbonate, propylene carbonate, and ethyl methyl carbonate may be used. These may be used singly, or may be used in combination of two or more. For the solute, for example, LiCl and LiPF₆ may be used. The electrolyte for the non-aqueous electrolyte secondary battery is not limited to the above-mentioned electrolytes.

The electrode material of the present invention may also be used as a negative electrode material for a lithium ion electric double layer capacitor. To be specific, the negative electrode for the capacitor may be formed only of the electrode material of the present invention. Or, the negative electrode may include the electrode material of the present invention, and a conductive carrier carrying the electrode material. For the conductive carrier, for example, a metal carrier may be used. The material forming the metal carrier is preferably, for example, copper, nickel, and iron.

The more the specific surface area of the electrode, the more the capacitance. The electrode material of the present invention has a large specific surface area, since it includes both of the particles capable of absorbing and desorbing lithium ions and the nanowires capable of absorbing and desorbing lithium ions. Therefore, by using the electrode material of the present invention, the capacitance of the electric double layer capacitor can be improved.

The electric double layer capacitor includes, for example, a negative electrode including the electrode material of the present invention, a positive electrode as the counter electrode, and an electrolyte. For the positive electrode material included in the positive electrode, a carbon material may be used. The electrolyte may include a non-aqueous solvent and a solute dissolved therein. For the non-aqueous solvent, for example, ethylene carbonate, propylene carbonate, and ethyl methyl carbonate may be used. These may be used singly, or may be used in combination of two or more. For the solute, LiCl and LiPF₆ may be used. The electrolyte for the electric double layer capacitor is not limited to the above-mentioned electrolytes.

Further, the electrode material of the present invention may be used as a material for varistors. For example, a varistor can be obtained by forming a layer of the particles and the nanowires on a conductive electrode, forming an oxide ceramic layer thereon, and further forming a conductive electrode on the oxide ceramic layer. For the oxide ceramics, for example, at least one selected from the group consisting of zinc oxide, silicon carbide, and silicon nitride may be used.

An electrode material for electrochemical devices of the present invention may be made, for example, by a method including the following steps:

(a) generating a thermal plasma in an atmosphere including an inert gas;

(b) placing a material containing silicon in the thermal plasma; and

(c) depositing a product obtained by allowing the raw material to pass through the thermal plasma on a predetermined carrier. The electrode material of the present invention may also be made by a method other than the producing method as mentioned above.

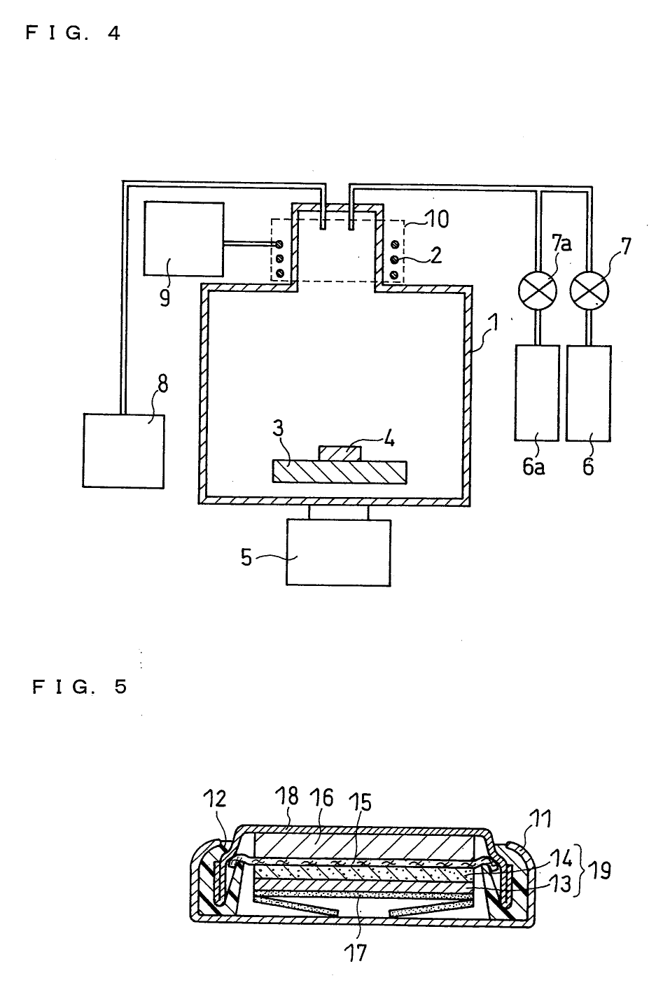

FIG. 4 shows an example of a manufacturing device used in the manufacturing method.

The manufacturing device in FIG. 4 includes a reaction chamber 1. At the upper portion of the reaction chamber 1, a torch 10 is disposed. In the torch 10, electrodes (or coils) 2 are disposed. The torch 10 preferably has a cooling mechanism for cooling the electrodes (or coils) 2. For the cooling mechanism, for example, a water-cooling mechanism may be used.

A supporting board 3 is disposed in the reaction chamber 1 directly below the torch 10, and at the face of the supporting board 3 facing the torch 10, a carrier 4 is disposed.

First, in the manufacturing device of FIG. 4, gas remained in the reaction chamber 1 is removed by an air displacement pump 5. For the air displacement pump 5, various vacuum pumps may be used. A vacuum pump which can reduce pressure to a high vacuum is used preferably. By using such a vacuum pump, the amount of impurities remained in the reaction chamber 1 can be significantly reduced. Thus, the impurities can be prevented from entering into the electrode material to be produced.

Afterwards, the reaction chamber 1 is filled with a gas for generating a thermal plasma. That is, the reaction chamber 1 is filed with an atmosphere including an inert gas.

In the manufacturing device, the thermal plasma is generated in the torch 10. Herein, the thermal plasma refers to a plasma with high thermal energy. The electrons, ions, and neutral particles included in the thermal plasma all have a high and substantially the same temperature. The temperature of the electrons, ions, and neutral particles is, at the highest portion, for example, 10000 to 20000K. The thermal plasma can be generated by allowing the pressure in the atmosphere including the inert gas in the reaction chamber 1 to be a high pressure of about atmospheric pressure.

The method for generating the thermal plasma is not particularly limited. For example, a thermal plasma can be generated by supplying an electric power to the electrode (or coil) 2 from a power source 9, and supplying the inert gas in a cylinder 6 to the torch 10 via a valve 7. For the inert gas, for example, argon gas, helium gas, neon gas, krypton gas, and xenon gas may be used.

To be specific, a thermal plasma can be generated in the torch 10 by using a pair of electrodes 2 by applying a direct current voltage between the electrodes 2 facing each other. A thermal plasma can also be generated in the torch 10 by using the coil 2 by applying a high-frequency voltage to the coil 2. Among these, the method using a high-frequency voltage is preferable. The coil to which a high-frequency voltage is applied can be disposed at the perimeter of the torch 10, which makes maintenance of the coil easy. Also, although there may be a possibility that the material forming the electrode enters into the electrode material as impurities in the case when a direct current voltage is applied to a pair of electrodes, in the method using a high-frequency voltage, plasma does not make a contact with the coil, and therefore the impurities of the material forming the coil can be prevented from being mixed therein. Further, since the raw material containing silicon can be easily evaporated or decomposed, the fiber diameter of the nanowires can be easily made nano-sized. In FIG. 4, the coil 2 is disposed at the perimeter of the torch 10 for applying a high-frequency voltage. In this case, the torch 10 can be made, for example, cylindrical. The size such as the inner diameter of the torch 10 is not particularly limited.

The speed of the supply of the inert gas into the torch 10 is preferably 5 to 500 L/min.

In the case when a high-frequency voltage is used, the frequency of the high-frequency voltage is preferably 1 to 100 MHz. The output applied to the coil is preferably 10 to 300 kW.

To generate a thermal plasma stably and efficiently, a diatomic molecule gas that is different from the inert gas is preferably supplied to the torch 10 with the inert gas. The diatomic molecule gas can be introduced to the torch 10 from the cylinder 6a via the valve 7a. For the diatomic molecule gas, hydrogen gas, nitrogen gas, and oxygen gas may be mentioned.

To stabilize the plasma, the flow rate of the inert gas and the flow rate of the diatomic molecule gas are preferably controlled by using a mass flow controller.

The supply speed of the diatomic molecule gas to the torch 10 is preferably 5 to 500 L/min.

The inert gas and the diatomic molecule gas are, for example, preferably supplied from the torch 10 in a direction toward the supporting board 3.

While the inert gas is being supplied to the torch 10, i.e., into the reaction chamber 1, the gas inside the reaction chamber 1 can be discharged outside with the air displacement pump 5, so as to make the pressure in the reaction chamber constant.

The raw material including silicon is supplied to the thermal plasma in the torch 10 by the raw material feeder 8. In the case of the thermal plasma generated by applying a high-frequency voltage to the coil, for example, the raw material may be supplied to the thermal plasma so as to move along the central axis of the thermal plasma.

The raw material is dissolved, evaporated or decomposed in the thermal plasma, while being allowed to move vertically downwardly from the torch 10 toward the carrier 4. Since the temperature of the thermal plasma decreases as the raw material moves from the torch 10 to the carrier 4, particles including silicon atoms and nanowires including silicon atoms are generated. These particles and nanowires are deposited on the carrier 4. That is, on the carrier 4, a product generated by allowing the raw material including silicon to pass through the thermal plasma (particles including silicon atoms and nanowires including silicon atoms) is deposited. The electrode material of the present invention can be thus made.

There has been reported that nanowires are more likely to be generated at a portion where a solid phase, a liquid phase, and a vapor phase coexist. In the above manufacturing method, by placing a raw material including silicon having a larger particle diameter than the particles including the silicon atoms in the thermal plasma, a portion of the raw material changes into liquid or gas, to generate a portion where a solid phase, a liquid phase, and a vapor phase coexist, and generate the particles including silicon atoms along with the nanowires.

The temperature near the carrier 4 is preferably for example 600 to 1500° C. The temperature near the carrier 4 can be controlled, for example, by adjusting the energy of the thermal plasma and the distance from the torch 10 to the supporting board 3. The temperature near the carrier 4 can be measured, for example, by measuring the infrared radiation emitted from near the carrier by using a radiation thermometer. The temperature near the carrier 4 can also be measured by setting a type R thermocouple with its surface covered by an insulating material with a high melting point such as alumina, and measuring the voltage of the thermocouple.

The raw material including silicon is preferably in powder form, since it is a low-cost. The raw material powder can be supplied, for example, by using a feeder using pressure gas, a feeder capable of belt conveyance, and a parts feeder.

The feeding of the raw material powder may be carried out continuously or intermittently.

For the raw material including silicon, for example, silicon powder and silicon oxide (SiOₓ) may be used.

The raw material including silicon is preferably supplied to the thermal plasma at a speed of 1 to 50 g/min.

The particle diameter of the particles, and the fiber diameter and the fiber length of the nanowires can be controlled by adjusting the manufacturing conditions.

For the material forming the reaction chamber 1, the torch 10, and the supporting board 3, those materials known in the art may be used. For example, for the reaction chamber 1, the material is not particularly limited, as long as an inert gas atmosphere can be created therein. For the material forming the torch 10, ceramics (quartz and silicon nitride) may be used. For the materials forming the supporting board 3, for example, stainless steel, titanium, nickel, and iron may be mentioned.

The materials forming the carrier 4 are not particularly limited. A conductive material, a semiconductive material, or a nonconductive material may be used. For the conductive material, various metal materials such as copper, nickel, and stainless steel, and carbon materials may be used. For the semiconductive material, silicon simple substance and SiC_{z} may be used. For the nonconductive material, various metal oxides and metal nitrides may be used. For the material forming the carrier 4, silicon oxide and silicon nitride may be used.

The electrode including the electrode material of the present invention can be made by using a conductive carrier, and depositing the particles including silicon atoms and nanowires including silicon atoms thereon. In this case, the conductive carrier functions as the current collector.

In the case when the particles including silicon atoms and the nanowires including silicon atoms are deposited on the semiconductive carrier or the nonconductive carrier, the layer including the particles and the nanowires may be removed from the carrier, and the obtained layer or powder including the particles and the nanowires may be used as the electrode material.

The particles and the nanowires including silicon atoms and at least one element selected from the group consisting of oxygen, nitrogen, and carbon can be obtained by further supplying a gas of oxygen source, a gas of nitrogen source, and/or a gas of carbon source to the torch 10. For the gas of oxygen source, for example, oxygen gas may be mentioned. For the gas of nitrogen source, for example, nitrogen gas may be mentioned. For the gas of carbon source, for example, ethylene gas may be mentioned.

The particles and the nanowires including silicon atoms and an atom of metal other than silicon atoms can be obtained by depositing an active material layer including the silicon particles and the silicon nanowires on the carrier including the metal atom, and heat-treating the carrier carrying the active material layer. Or, the particles and the nanowires including silicon atoms, and a metal atom other than the silicon atoms can also be made by placing a raw material including silicon, and a raw material including the metal atom in the torch 10.

### EXAMPLES

In the following Examples, electrode materials were made by using the manufacturing device as shown in FIG. 4. For the thermal plasma, a high-frequency thermal plasma was used. The obtained electrode materials were used as the electrode materials for a non-aqueous electrolyte secondary battery. In Examples below, as shown in FIG. 5, a coin-type test battery was made, and a metal lithium was used as a counter electrode. As described above, an electrode including an electrode material of the present invention functions as a negative electrode, in the case of a non-aqueous electrolyte secondary battery using for example a lithium-containing composite oxide as the positive electrode active material.

### Example 1

### Electrode Material Preparation

A supporting board 3 was fixed at a position directly below and about 300 mm from a torch 10. On the supporting board 3 in a reaction chamber 1, a copper foil with a thickness of 75 μm was disposed as a carrier 4. The copper foil functions as a current collector in the battery.

Afterwards, the gas in the reaction chamber 1 was displaced by using an air displacement pump 5, and then the reaction chamber 1 was charged with an argon gas. Such operation was repeated several times, to render the atmosphere in the reaction chamber 1 an argon gas atmosphere.

Then, while introducing an argon gas at a flow rate of 200 L/min from a cylinder 6 and a hydrogen gas at a flow rate of 10 L/min from a cylinder 6a to the torch 10, a high-frequency voltage of 3 MHz was applied to the coil 2, to generate a thermal plasma. The output applied to the coil was set to 100 kW. At this time, the air displacement pump 5 was used to discharge gas in the reaction chamber 1, so that the pressure in the reaction chamber 1 was constant.

Silicon powder (raw material) with a particle diameter of about 10 μm was introduced into the torch 10 at a speed of 25 g/min by using a raw material feeder 8 to form an active material layer on the copper foil. The active material layer formation was carried out for 10 minutes. An electrode 19 including a copper foil 13 and an active material layer 14 carried thereon was thus obtained. The thickness of the active material layer 14 was about 10 μm.

As the obtained electrode was observed by an electron microscope, it was found that silicon particles with a particle diameter of about 5 μm, and silicon nanowires entangled to form a network, such as those shown in FIG. 1, were deposited on the copper foil. Two silicon particles adjacent to each other were in contact with the network of silicon nanowires. The fiber diameter of the produced nanowires was 0.03 to 0.05 μm (30 to 50 nm).

### (Battery Assembly)

A coin-type test battery as shown in FIG. 5 was made as in below. The steps below were carried out in a dry air with a dew point of −50° C. or less.

First, a metal lithium foil 16 with a diameter of 17 mm and a thickness of 0.3 mm was obtained. The obtained metal lithium foil 16 was disposed at an inner bottom face of a stainless steel-made sealing body 18.

Then, on the metal lithium foil 16, a polyethylene-made separator 15 was stacked. Afterwards, the electrode 19 obtained as described above was disposed on the separator 15, so that the active material layer 14 faced the metal lithium foil 16 with the separator 15 interposed therebetween. On the electrode 19, a disc spring 17 was disposed.

Then, an electrolyte was injected to fill the sealing body 18, and the stainless steel-made case 11 was disposed on the disc spring 17. The end portion of the case 11 was crimped to the sealing body 18 with a stainless steel-made gasket 12 interposed therebetween, to seal the battery. The electrolyte was prepared by dissolving LiPF₆ in a non-aqueous solvent including ethylene carbonate and ethyl methyl carbonate at a volume ratio of 1:3 with a concentration of 1.25 mol/L.

A battery of Example 1 was thus made.

### Example 2

An electrode was made in the same manner as Example 1, except that to the torch 10, an oxygen gas was further introduced at a flow rate of 5 L/min. Observation of the thus obtained electrode with an electron microscope revealed that particles with a particle diameter of about 5 μm, and nanowires entangled with each other to form a network were generated. The fiber diameter of the produced nanowires was 0.03 to 0.05 μm. By using an X-ray micro analyzer, it was confirmed that the particles and the nanowires included 1:0.2 molar ratio of silicon and oxygen. To be specific, the composition of the particles and the nanowires was SiO_{0.2}.

By using the obtained electrode, a battery of Example 2 was made in the same manner as Example 1.

### Example 3

An electrode was made in the same manner as Example 1, except that to the torch 10, a nitrogen gas was further introduced at a flow rate of 10 L/min. Observation of the thus obtained electrode with an electron microscope revealed that particles with a particle diameter of about 5 μm and nanowires entangled with each other to form a network were generated. The fiber diameter of the produced nanowires was 0.03 to 0.05 μm. By using an X-ray micro analyzer, it was confirmed that the particles and the nanowires included 1:0.1 molar ratio of silicon and nitrogen. To be specific, the composition of the particles and the nanowires was SiN_{0.1}.

By using the obtained electrode, a battery of Example 3 was made in the same manner as Example 1.

### Example 4

An electrode was made in the same manner as Example 1, except that to the torch 10, an ethylene gas was further introduced at a flow rate of 10 L/min. Observation of the thus obtained electrode with an electron microscope revealed that particles with a particle diameter of about 5 μm, and nanowires entangled to form a network were generated. The fiber diameter of the produced nanowire was 0.03 to 0.05 μm. By using an X-ray micro analyzer, it was confirmed that the particles and the nanowires included 1:0.15 molar ratio of silicon and carbon. To be specific, the composition of the particles and the nanowires was SiC_{0.15}.

By using the obtained electrode, a battery of Example 4 was made in the same manner as Example 1.

### Example 5

The electrode thus obtained in Example 1 was put into an atmosphere furnace, and heat-treated in an argon gas atmosphere at 500° C. By using an X-ray micro analyzer, it was confirmed that silicon particles and silicon nanowires present near the copper foil included copper atoms of about 1 wt %.

A battery of Example 4 was made in the same manner as Example 1, using the electrode after the heat-treatment.

### Comparative Example 1

The silicon particles with a particle diameter of about 5 μm, graphite as a conductive agent, and styrene butadiene rubber as a binder were mixed in a weight ratio of 70:23:7. The obtained mixture was dried at 120° C. for 12 hours to obtain an electrode material mixture.

Battery of Comparative Example 1 was made in the same manner as Example 1, except that the electrode material mixture made as described above was used instead of the electrode 19 made in Example 1. In Comparative Example 1, the thickness of the active material layer was 15 μm.

### Comparative Example 2

Silicon particles with a particle diameter of about 5 μm was placed in an alumina crucible, and the crucible was placed in an air atmosphere furnace. The temperature of the air atmosphere furnace was increased to 800° C., and the temperature was kept for about 3 hours, to obtain silicon oxide particles.

By using an X-ray micro analyzer, it was confirmed that the silicon oxide particles included 1:0.2 molar ratio of silicon and oxygen. To be specific, the composition of the silicon oxide particles was SiO_{0.2}.

A battery of Comparative Example 2 was made in the same manner as Comparative Example 1, except that silicon oxide particles were used instead of the silicon particles.

### Comparative Example 3

Silicon powder with a particle diameter of about 5 μm was placed in an alumina crucible, and the crucible was placed in an atmosphere furnace. Then, while a mixed gas of 80 volume % nitrogen gas and 20 volume % hydrogen gas was allowed to flow into the atmosphere furnace at a flow rate of 3 NL/min, the temperature of the atmosphere furnace was increased to 1200° C., and the temperature was kept for 5 hours. The silicon nitride particles were thus obtained.

By using an X-ray micro analyzer, it was confirmed that the silicon nitride particles included 1:0.1 molar ratio of silicon and nitride. To be specific, the composition of the silicon nitride particles was SiN_{0.1}.

A battery of Comparative Example 3 was made in the same manner as Comparative Example 1, except that the silicon nitride particles were used instead of the silicon particles.

### Comparative Example 4

Silicon powder with a particle diameter of about 5 μm was placed in an alumina crucible, and the crucible was placed in an atmosphere furnace. Then, while introducing a mixed gas of 50 volume % argon gas and 50 volume % ethylene gas into the atmosphere furnace at a flow rate of 3 NL/min, the temperature of the atmosphere furnace was increased to 1250° C., and the temperature was kept for 5 hours. The silicon particles including carbon atoms were thus obtained.

By using an X-ray micro analyzer, it was confirmed that the silicon particles including carbon atoms included 1:0.15 molar ratio of silicon and carbon. To be specific, the composition of the silicon particles including carbon atoms was SiC_{0.15}.

A battery of Comparative Example 4 was made in the same manner as Comparative Example 1, except that the silicon particles containing the carbon atoms were used instead of the silicon particles.

### [Evaluation]

The batteries of Examples 1 to 5 and Comparative Examples 1 to 4 were examined for their discharge performance. To be specific, constant current charge and discharge were repeated with a current density of 100 ƒA/cm² and within a range of 0 to 1.5 V (Li/Li⁺ base). The current density is a current value per unit area of the electrode 19.

The discharge capacity of the first cycle (initial discharge capacity) and the discharge capacity of the 5th cycle were measured. The measurement temperature was 20° C. The results are shown in Table 1. In Table 1, the initial discharge capacity and the discharge capacity of the 5th cycle were shown as a discharge capacity per unit weight of the active material.

TABLE 1

| | Initial | Discharge |
|---|---|---|
| | Discharge | Capacity at |
| | Capacity | the 5th Cycle |
| | (mAh/g) | (mAh/g) |
| Example 1 | 2400 | 2150 |
| Example 2 | 1550 | 1450 |
| Example 3 | 1650 | 1550 |
| Example 4 | 1250 | 1150 |
| Example 5 | 2000 | 1900 |
| Comp. Ex. 1 | 2200 | 1600 |
| Comp. Ex. 2 | 1400 | 1190 |
| Comp. Ex. 3 | 1600 | 1350 |
| Comp. Ex. 4 | 1200 | 1050 |

Comparisons were made between the battery of Example 1 and the battery of Comparative Example 1. The battery of Example 1 had a higher initial discharge capacity than the battery of Comparative Example 1, and decline in the discharge capacity at the 5th cycle was kept low. The battery of Example 1 included nanowires including silicon, other than the particles including silicon. In the battery of Example 1 after the charge and discharge cycle, it was confirmed that the silicon particles and the silicon nanowires were in close contact without being removed from the copper foil. Probably, with the further inclusion of the nanowires, even with the expansion of the active material while being charged, the removal of the active material from the current collector was further curbed. Thus, the decline in the initial discharge capacity and the discharge capacity at the 5th cycle was moderated.

Comparisons were made between the battery of Example 2 and the battery of Comparative Example 2. The battery of Example 2 had a higher initial discharge capacity than the battery of Comparative Example 2, and the decline in the discharge capacity at the 5th cycle was kept low. The battery of Example 2 included, other than the particles including silicon atoms and oxygen atoms, the nanowires including silicon atoms and oxygen atoms. In the battery of Example 2 after charge and discharge cycle, it was confirmed that the particles and the nanowires were in close contact, without being removed from the copper foil. Provably, in the case of Example 2 as well, similarly to the case of Example 1, the removal of the active material from the current collector was curbed, and the decline in the initial discharge capacity and the discharge capacity at the 5th cycle was moderated.

Comparisons were made between the battery of Example 3 and the battery of Comparative Example 3. The battery of Example 3 had a higher initial discharge capacity than the battery of Comparative Example 3, and the decline in the discharge capacity at the 5th cycle was kept low. The battery of Example 3 included, other than the particles including silicon atoms and nitrogen atoms, the nanowires including silicon atoms and nitrogen atoms. In the battery of Example 3 after the charge and discharge cycle, it was confirmed that the particles and the nanowires were in close contact without being removed from the copper foil. In Example 3 as well, probably, the removal of the active material from the current collector was curbed, and the decline in the initial discharge capacity and the discharge capacity at the 5th cycle was moderated.

Comparisons were made between the battery of Example 4 and the battery of Comparative Example 4. The battery of Example 4 had a higher initial discharge capacity than the battery of Comparative Example 4, and the decline in the discharge capacity at the 5th cycle was kept low. The battery of Example 4 included, other than the particles including silicon atoms and carbon atoms, the nanowires including silicon atoms and carbon atoms. In the battery of Example 4 after the charge and discharge cycle, it was confirmed that the particles and the nanowires were in close contact without being removed from the copper foil. In Example 4 as well, probably, the removal of the active material from the current collector was curbed, and the decline in the initial discharge capacity and the discharge capacity at the 5th cycle was moderated.

The battery of Example 5 had a lower initial discharge capacity than the battery of Example 1, but the decline in the discharge capacity at the 5th cycle was kept low. Probably, since the silicon particles and the silicon nanowires included copper atoms, the initial discharge capacity declined, but the electron conductivity of the silicon particles and the silicon nanowires increased, and as a result, the capacity decline when charge and discharge were repeated was kept low. In the battery of Example 5 after the charge and discharge cycle as well, it was confirmed that the particles and the nanowires were in close contact, without being removed from the copper foil.

As described above, in the non-aqueous electrolyte secondary batteries of Examples 1 to 5, the removal of the active material including particles with silicon atoms and the nanowires with silicon atoms from the current collector can be curbed. Therefore, an electrochemical device including the electrode material of the present invention has a high capacity and excellent cycle performance.

An electrochemical device including an electrode material of the present invention may be used, for example, as a power source for driving mobile electronic devices such as for example personal computers and mobile phones. Further, the electrochemical device may also be used for stabilizing voltage and protecting a circuit.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

1. An electrode material for an electrochemical device, said electrode material comprising:
a plurality of particles capable of absorbing and desorbing lithium, and a plurality of nanowires capable of absorbing and desorbing lithium,
wherein said particles and said nanowires include silicon atoms,
said plurality of nanowires are entangled with each other to form a network, and
said network is in contact with at least two of said plurality of particles.

2. The electrode material for an electrochemical device in accordance with claim 1, wherein said particles and said nanowires further include at least one element selected from the group consisting of oxygen, carbon, and nitrogen.

3. The electrode material for an electrochemical device in accordance with claim 1, wherein at least one of said particles and said nanowires further include a metal element other than said silicon atoms.

4. An electrode for an electrochemical device, the electrode comprising the electrode material in accordance with claim 1 and a carrier for carrying said electrode material.

5. The electrode for an electrochemical device in accordance with claim 4, wherein said carrier includes at least one material selected from the group consisting of copper, nickel, and stainless steel.

6. An electrochemical device comprising the electrode in accordance with claim 4, a counter electrode, and an electrolyte.

7. The electrochemical device in accordance with claim 6, wherein the electrochemical device is a non-aqueous electrolyte secondary battery or an electric double layer capacitor.

8. A method for producing the electrode material for an electrochemical device in accordance with claim 1, the method comprising:
(a) generating a thermal plasma in an atmosphere including an inert gas;
(b) placing a raw material including silicon in said thermal plasma; and
(c) depositing a product obtained by allowing said raw material to pass through said thermal plasma on a predetermined carrier.
